(19) United States
(12) Patent Application Publication
(10) Pub. No.: US 2013/0139866 A1
(43) Pub. Date: Jun. 6, 2013

(54) Ceramic Plate

(71) Applicants: Joshua E. Moczygemba, Wylie, TX (US); James L. Bierschenk, Rowlett, TX (US)

(72) Inventors: Joshua E. Moczygemba, Wylie, TX (US); James L. Bierschenk, Rowlett, TX (US)

(73) Assignee: MARLOW INDUSTRIES, INC., Dallas, TX (US)

(21) Appl. No.: 13/309,220

(22) Filed: Dec. 1, 2011

(51) Int. Cl. H01L 35/30; C23C 4/08; H05K 13/00; C23C 4/18; C23C 4/12; H01L 35/02; C23F 1/02

(52) U.S. Cl. 136/230; 427/456; 216/95; 427/448; 29/592.1

(57) ABSTRACT

In one embodiment, a method for forming a metallized ceramic includes thermal spraying metal directly onto a first side of a ceramic plate. The metal comprising aluminum. The method also includes densifying the thermally ceramic plate after spraying the metal onto the first side of the ceramic plate.

### GOVERNMENT RIGHTS

A portion or all of this disclosure may have been made with Government support under government contract number W909MY-09-C-0061 awarded by the United States Army. The Government may have certain rights in this disclosure.

### TECHNICAL FIELD

This disclosure relates generally to ceramic plates and more particularly to an improved metallized ceramic plate.

### BACKGROUND

The basic theory and operation of thermoelectric devices has been developed for many years. Presently available thermoelectric devices used for cooling typically include an array of thermocouples which operate in accordance with the Peltier effect. Thermoelectric devices may also be used for heating, power generation and temperature sensing.

Thermoelectric devices may be described as essentially small heat pumps which follow the laws of thermodynamics in the same manner as mechanical heat pumps, refrigerators, or any other apparatus used to transfer heat energy. A principal difference is that thermoelectric devices function with solid state electrical components (thermoelectric elements or thermocouples) as compared to more traditional mechanical/fluid heating and cooling components.

Thermoelectric materials such as alloys of Bi₂Te₃, PbTe and BiSb were developed thirty to forty years ago. More recently, semiconductor alloys such as SiGe have been used in the fabrication of thermoelectric devices. Typically, a thermoelectric device incorporates both a P-type semiconductor and an N-type semiconductor alloy as the thermoelectric materials.

Cooling applications and power generation applications may require thermoelectric devices to operate at higher temperatures or in environments where thermally cycling occurs. Existing techniques have been unable to produce effective solutions.

Metallized ceramics may be used in the thermoelectric applications discussed above or in other applications. Metallized ceramics have been susceptible to failure due to high temperatures or thermal cycling. For example, copper metallizations have proven susceptible to failure due to its tensile strength and to a mismatch between the coefficient of thermal expansion of copper and the ceramic plate. Failures include fracturing of the plate and delamination of the metallization. Effective solutions are still needed.

### SUMMARY

In one embodiment, a method for forming a metallized ceramic includes thermal spraying metal directly onto a first side of a ceramic plate. The metal comprising aluminum. The method also includes densifying the thermally ceramic plate after spraying the metal onto the first side of the ceramic plate.

In some embodiments, thermal spraying metal onto the first side of the ceramic plate may include arc spraying the metal. Densifying the thermally sprayed metal comprises heating the ceramic plate under an inert cover gas.

In one embodiment, a device includes a ceramic plate and at least one portion of metal directly bonded to a first side of the ceramic plate without an interface layer. The metal includes aluminum. The one portion of metal is configured to adhere to the ceramic plate while the at least one plate is in an environment with a temperature of at least 200 degrees Celsius.

Depending on the specific features implemented, particular embodiments may exhibit some, none, or all of the following technical advantages. Adhesion of metallizations on a ceramic plate may be improved. A metallized ceramic plate may be resilient to thermal cycling. Other technical advantages will be readily apparent to one skilled in the art from the following figures, description and claims.

### BRIEF DESCRIPTION OF THE DRAWINGS

Reference is now made to the following description taken in conjunction with the accompanying drawings, wherein like reference numbers represent like parts and which:

FIGS. 1A and 1B illustrate one embodiment of a ceramic metallized plate;

FIGS. 2A-2B illustrate one embodiment of a thermoelectric device with metallized ceramic plates;

FIG. 3 illustrates one embodiment of a power device with metallized ceramic plates;

FIG. 4 is a flowchart illustrating one embodiment of forming an thermoelectric device; and

FIG. 5 is a flowchart illustrating one embodiment of forming metallized ceramics.

### DETAILED DESCRIPTION

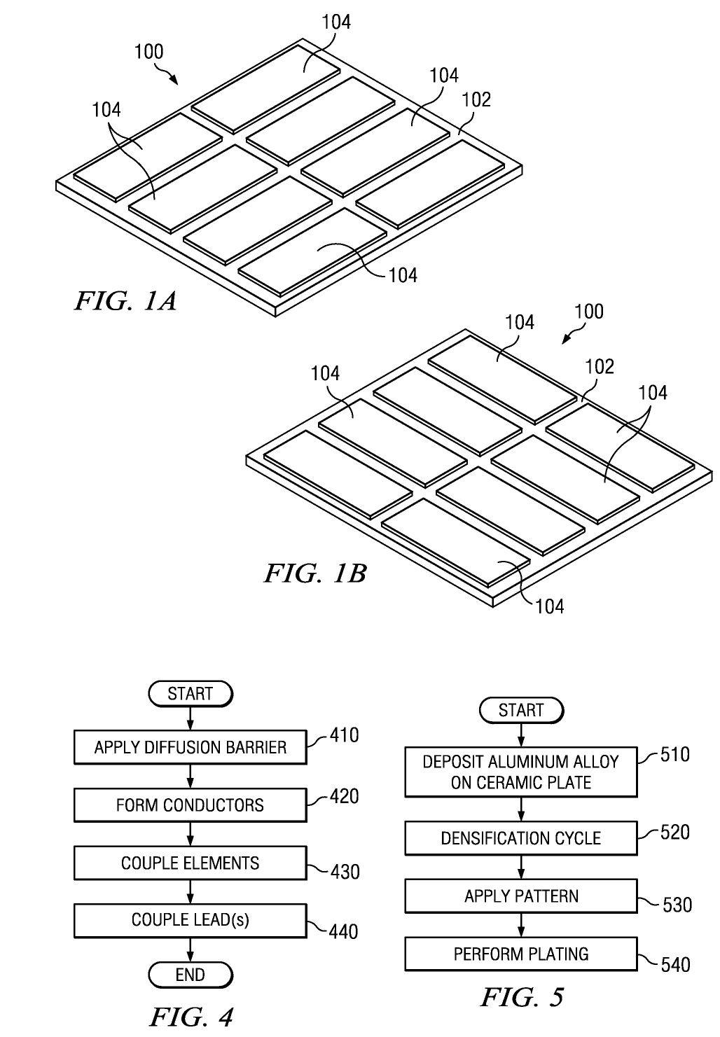

FIGS. 1A-1B illustrates one embodiment of a metallized ceramic plate 100. FIG. 1A illustrates one side of plate 100 and FIG. 1B illustrates another side of plate 100. Plate 100 comprises substrate 102 that has metallizations 104 formed on it.

In some embodiments, substrate 102 may be or comprise ceramic material. Examples of ceramic material used to implement substrate 102 are beryllium oxide, aluminum nitride, and silicon carbide.

In some embodiments, metallizations 104 may be formed on substrate 102 without an interface layer (i.e., metallizations 104 may be directly bonded to substrate 102). Metallizations 104 may be electrically separated from each other. In some embodiments, metallizations 104 may be formed by spraying the base metal (e.g., aluminum or aluminum compounds or alloys). For example, aluminum wire (or aluminum alloy) may be sprayed using arc spraying or plasma spraying onto substrate 102. A densification cycle may be performed on plate 100 with the sprayed aluminum metal in order to densify the sprayed aluminum metal. For example, plate 100 may be heated at a temperature just above the melting point of the metal sprayed on plate 100 (e.g., aluminum alloy) under an inert cover gas (e.g., nitrogen). Plate 100 may then be patterned with an etch mask to form metallizations 104. Patterns may also be formed by applying a mask to plate 100 prior to applying metallizations 104 to plate 100 and then removing the mask after metallizations 104 have been applied to plate 100. In some embodiments, forming metallizations 104 in this manner may provide an advantage in that plate 100 with metallizations 104 may be resilient to high temperature (e.g., greater than 200 degrees Celsius) cycles. As another example advantage, forming metallizations 104 in this manner may lead to improved adhesion of metallizations 104 to substrate 102.

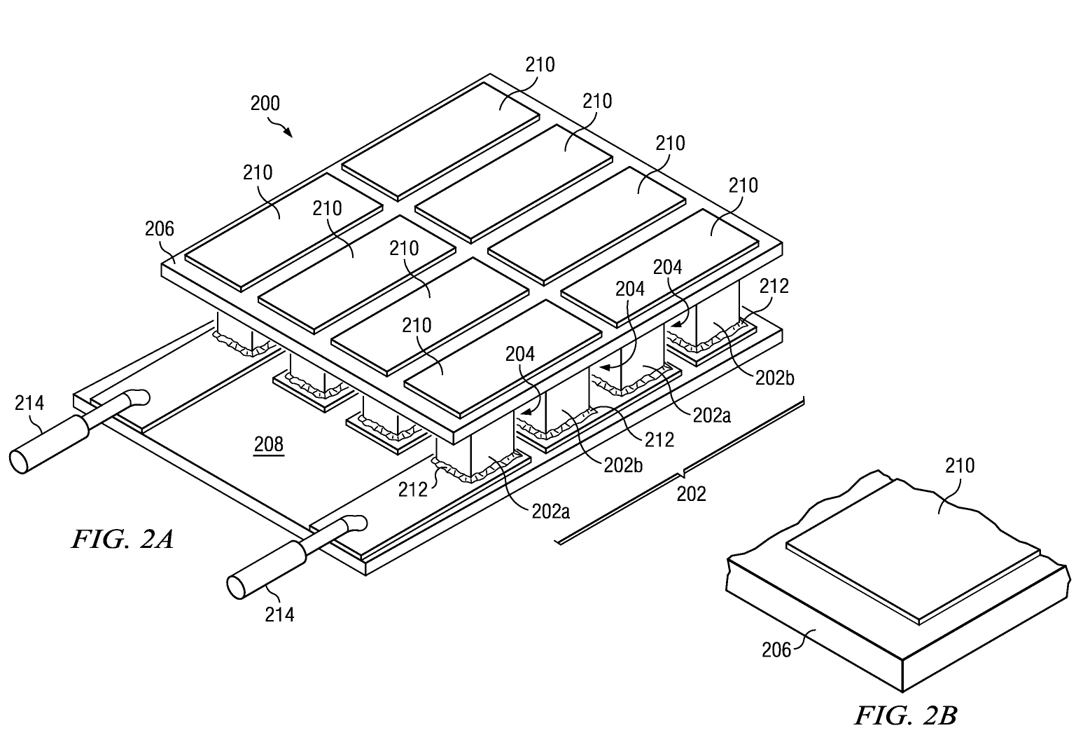

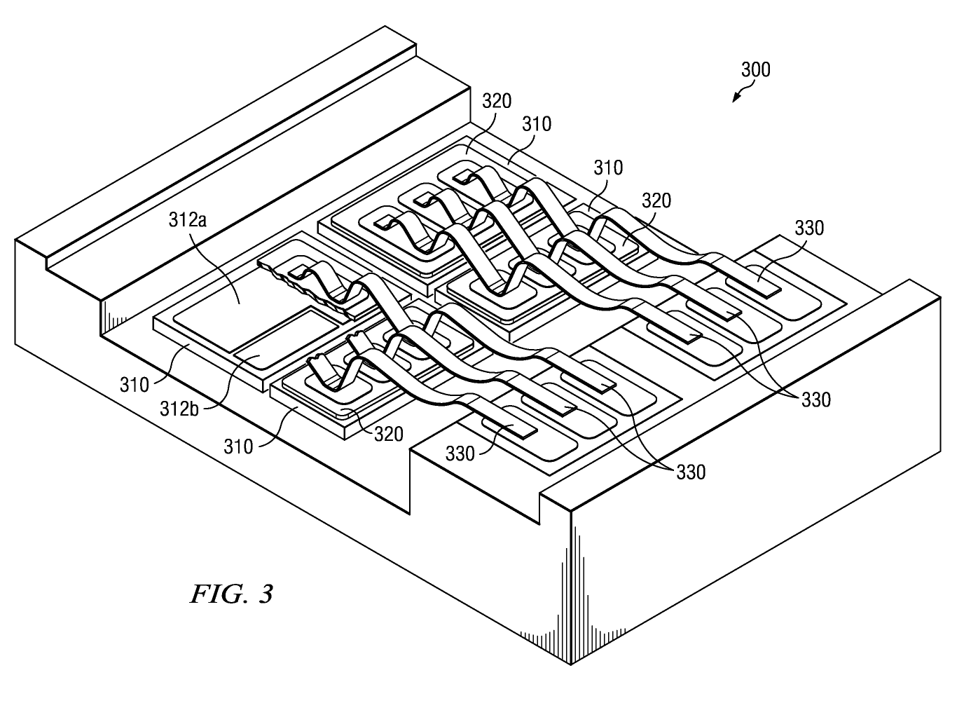

In some embodiments, plate 100 may be useful in various applications. Examples of configurations of plate 100 used in thermoelectric applications and in power system applications are given below with respect to FIGS. 2 and 3, respectively. Plate 100 may be used in various applications where resilience in high temperature (e.g., greater than 200 degrees Celsius) cycling environments is helpful.

FIG. 2A illustrates one embodiment of thermoelectric device 200 that includes metallized ceramics. Thermoelectric device 200 may include thermoelectric elements 202 fabricated from dissimilar semiconductor materials such as N-type thermoelectric elements 202a and P-type thermoelectric elements 202b. Thermoelectric elements 202 are typically configured in a generally alternating N-type element to P-type element arrangement and typically include an air gap 204 disposed between adjacent N-type and P-type elements. In many thermoelectric devices, thermoelectric materials with dissimilar characteristics are connected electrically in series and thermally in parallel.

Thermoelectric device 200 may be used as a heater, cooler, electrical power generator, and/or temperature sensor. If thermoelectric device 200 were designed to function as an electrical power generator, leads 214 would represent the output terminals from such a power generator operating between hot and cold temperature sources.

Examples of thermoelectric devices and methods of fabrication are shown in U.S. Pat. No. 5,064,476 titled Thermoelectric Cooler and Fabrication Method; U.S. Pat. No. 5,171,372 titled Thermoelectric Cooler and Fabrication Method; and U.S. Pat. No. 5,576,512 titled Thermoelectric Apparatus for Use With Multiple Power Sources and Method of Operation.

N-type semiconductor materials generally have more electrons than necessary to complete the associated crystal lattice structure. P-type semiconductor materials generally have fewer electrons than necessary to complete the associated crystal lattice structure. The “missing electrons” are sometimes referred to as “holes.” The extra electrons and extra holes are sometimes referred to as “carriers.” The extra electrons in N-type semiconductor materials and the extra holes in P-type semiconductor materials are the agents or carriers which transport or move heat energy between cold side or cold plate 206 and hot side or hot plate 208 through thermoelectric elements 200 when subject to a DC voltage potential. These same agents or carriers may generate electrical power when an appropriate temperature difference is present between cold side 206 and hot side 208. Leads 214 may be coupled to plate 208 in a manner that withstands high temperature environments, such as resistance welding, tungsten inert gas (TIG) welding, and laser welding.

In some embodiments, thermoelectric elements 202 may include high temperature thermoelectric material. Examples of high temperature thermoelectric materials include lead telluride (PbTe), lead germanium telluride (PbGeTe), TAGS alloys (such as (GeTe)0.85(AgSbTe2)0.15), bismuth telluride (Bi2Te3), and skutterudites.

In some embodiments, thermoelectric elements 202 may include a diffusion barrier that includes refractory metals (e.g., a metal with a melting point above 1,850° C.). Suitable refractory metals may include those that are metallurgically compatible with high temperature thermoelectric materials and metallurgically compatible with other components of thermoelectric device 200. For example, a molybdenum diffusion barrier may be used. This may be advantageous in that molybdenum may be metallurgically compatible with various aspects of thermoelectric device 200. For example, as further discussed below, thermoelectric device 200 may include an aluminum braze that is metallurgically compatible with a molybdenum diffusion barrier. Such a diffusion barrier may prevent or reduce the chance or occurrence of Kirkendall voiding in thermoelectric device 200. Other suitable examples of a diffusion barrier that has similar properties to molybdenum include tungsten, nickel, and titanium.

In some embodiments, alternating thermoelectric elements 202 of N-type and P-type semiconductor materials may have their ends connected by electrical conductors 210. Conductors 210 may be metallizations formed on thermoelectric elements 202 and/or on the interior surfaces of plates 206 and 208. Conductors 210 may include aluminum. Ceramic materials may be included in plates 206 and 208 which define in part the cold side and hot side, respectively, of thermoelectric device 200. In some embodiments, the ceramic materials may provide electrical isolation from hot and cold side sources. Aluminum metallized ceramics may accommodate thermal stresses (e.g., due to high temperature exposure) of the ceramic/aluminum bond. Examples of suitable ceramic materials include aluminum oxide, aluminum nitride, and beryllium oxide.

FIG. 2B illustrates one embodiment of a close-up view of plate 206 with conductors 210. In some embodiments, there may be no interface layer between plate 206 and conductors 210 as conductors 210 may be directly bonded to plate 206. In some embodiments, conductors 210 may be formed by spraying the base metal (e.g., aluminum or aluminum compounds or alloys). For example, aluminum wire (or aluminum alloy) may be sprayed using arc spraying or plasma spraying onto plate 206. A densification cycle may be performed on the plate 206 with the sprayed aluminum metal in order to densify the sprayed aluminum metal. For example, plate 206 may be heated at a temperature just above the melting point of the metal sprayed on plate 206 (e.g., aluminum alloy) under an inert cover gas (e.g., nitrogen). Plate 206 may then be patterned with an etch mask to form conductors 210. In some embodiments, forming conductors 210 in this manner may provide an advantage in that plates 206 and 208 with conductors 210 may be resilient to high temperature (e.g., greater than 200 degrees Celsius) cycles. As another example advantage, forming conductors 210 in this manner may lead to improved adhesion of conductors 210 to plates 206 and 208.

In some embodiments, thermoelectric elements 202 may be coupled to plates 206 and 208 using medium 212. Medium 212 may include brazes and/or solders. For example, aluminum-based brazes and/or solders may be used, such as aluminum silicon (AlSi) braze family and/or zinc-aluminum (ZnAl) solder. In some embodiments, using such brazes and/or solders may provide for operation in a high temperature (e.g., greater than 200 degrees Celsius) environment and allow for flexible joints. Kirkendall voiding may be prevented or reduced.

In some embodiments, using one or more of the configurations discussed above, thermoelectric device 200 may be suitable as a fixed-joint, high temperature thermoelectric generator that is capable of being used in high temperature applications. For example, a thermoelectric generator built using skutterudite thermoelectric elements that include a molybdenum diffusion barrier, conductors formed by aluminum metallizations, and aluminum based brazes may result in a device that can operate with at least one of its plates (such as plates 206 or 208) in an environment with a temperature at or greater than 500 degrees Celsius. As another example, a thermoelectric generator built using bismuth telluride thermoelectric elements that include a molybdenum diffusion barrier, conductors formed by aluminum metallization, and zinc-aluminum (ZnAl) solder may result in a device that can operate with at least one of its plates (such as plates 206 or 208) at a temperature greater than 300 degrees Celsius. As another example, thermoelectric device 200 may be used in automotive waste heat recovery applications. One advantage present in certain embodiments may be that the use of aluminum metallization on plates 206 and 208 and the manner in which the metallization is formed (e.g., as described below with respect to FIGS. 4 and 5) may provide thermoelectric device 200 with resilience to thermal cycling which can be useful in high temperature (e.g., greater than 200 degrees Celsius) power generation applications.

FIG. 3 illustrates one embodiment of a power controller 300 with metallized ceramic plates 310. Controller 300 includes modules 320 (e.g., high power modules) coupled to plates 310. Cables 330 couple various modules 320. As an example, power controller 300 may be suitable to implement a motor controller.

In some embodiments, plates 310 may be implemented using the examples discussed above with respect to plate 100 of FIG. 1. Each of plates 310 includes metallizations 312a and 312b that are electrically separated from one another. Plate 310 may be implemented using silicon carbide or other suitable ceramic materials. In some embodiments, metallizations 312a and 312b may be formed by spraying the base metal (e.g., aluminum or aluminum compounds or alloys). For example, aluminum wire (or aluminum alloy) may be sprayed using arc spraying or plasma spraying onto plate 310. A densification cycle may be performed on plate 310 with the sprayed aluminum metal in order to densify the sprayed aluminum metal. For example, plate 310 may be heated at a temperature just above the melting point of the metal sprayed on plate 310 (e.g., aluminum alloy) under an inert cover gas (e.g., nitrogen). Plate 310 may then be patterned with an etch mask to form metallizations 312a and 312b. In some embodiments, forming metallizations 312a and 312b in this manner may provide an advantage in that plate 310 with metallizations 312a and 312b may be resilient to high temperature (e.g., greater than 200 degrees Celsius) cycles. As another example advantage, forming metallizations 312a and 312b in this manner may lead to improved adhesion of metallizations 312a and 312b to plate 310.

FIG. 4 is a flowchart illustrating one embodiment of forming an thermoelectric device. For example, the steps illustrated in FIG. 4 may be used to form a thermoelectric generator. In general, the steps illustrated in FIG. 4 may be combined, modified, or deleted where appropriate, and additional steps may also be added to the example operation. Furthermore, the described steps may be performed in any suitable order.

At step 410, in some embodiments, a diffusion barrier may be applied to one or more thermoelectric elements. The diffusion barrier may be or include refractory metals, such as molybdenum, tungsten, and titanium. For example, a molybdenum diffusion barrier metallization may be applied at this step.

At step 420, in some embodiments, conductors may be formed. The conductors may be metallizations formed on the thermoelectric elements and/or formed on plates (e.g., on the interior surfaces of the plates). The plates may be ceramic plates. The conductors may be formed of aluminum.

In some embodiments, the conductors may be formed by spraying the base metal (e.g., aluminum or aluminum compounds or alloys) onto the plates. For example, aluminum wire (or aluminum alloy) may be sprayed using arc spraying or plasma spraying onto a ceramic plate. In some embodiments, the sprayed base metal may not be fully dense. Hence, a densification cycle may be performed on the plate with the sprayed aluminum metal. For example, the plate may be heated at a temperature just above the melting point of the metal sprayed on the plate (e.g., aluminum alloy) under an inert cover gas (e.g., nitrogen). The plate may then be patterned with an etch mask to form the conductors.

In some embodiments, a mask may be placed on the plates before the base metal is sprayed onto the plates. After the metal is sprayed, the mask may be removed. As a result, a pattern may be formed on the plates.

At step 430, in some embodiments, plates may be coupled to the thermoelectric elements. For example, the thermoelectric elements may be coupled to the interior surfaces of two plates where conductors have been formed (e.g., at step 420) such that the thermoelectric elements may be disposed between the two plates. The thermoelectric elements may be coupled to conductors on the plates such that an N-type thermoelectric element is coupled to a P-type thermoelectric element. The plates may be coupled to the thermoelectric elements using brazes and/or solders. For example, aluminum-based brazes and/or solders may be used, such as aluminum silicon (AlSi) braze family and/or zinc-aluminum (ZnAl) solder.

At step 440, in some embodiments, leads may be coupled to at least one of the plates. This may be performed using resistance welding, tungsten inert gas (TIG) welding, or laser welding. The leads may be coupled such that electricity generated by the thermoelectric device may be sent through the leads to another device. As another example, the leads may be coupled such that electricity may be applied to the thermoelectric device.

FIG. 5 is a flowchart illustrating one embodiment of forming metallized ceramics. In general, the steps illustrated in FIG. 5 may be combined, modified, or deleted where appropriate, and additional steps may also be added to the example operation. Furthermore, the described steps may be performed in any suitable order.

At step 510, in some embodiments, metal is deposited on a ceramic plate. The ceramic plate may be implemented like ceramic plate 100 of FIG. 1 (e.g., beryllium oxide, aluminum nitride, or silicon carbide). The metal used at this step may be the same kind (or similar in kind) to that used in conductors 210 of FIGS. 2A and 2B (e.g., aluminum wire or aluminum alloy). As examples, the metal may be deposited at this step using thermal spraying (e.g., arc spraying or plasma spraying) or other suitable methods for directly bonding the metal. In some embodiments, depositing the metal on the ceramic plate at this step may include spraying the metal in an inert cover gas (e.g., nitrogen). As an example, 10-20 mm of metal (e.g., aluminum or aluminum alloy) may be deposited onto the ceramic plate at this step.

At step 520, in some embodiments, a densification cycle may be applied to the ceramic plate with the deposited metal in order to densify the deposited metal. For example, the plate may be heated at a temperature just above the melting point of the metal sprayed on the plate (e.g., aluminum alloy) under an inert cover gas (e.g., nitrogen). A belt-type oven may be used at this step. In some embodiments, this step may provide an advantage in that it may cause improved adhesion between the ceramic plate and the deposited metal.

At step 530, in some embodiments, a pattern may be formed on the metallized ceramic. For example, an etch mask to form the pattern using a ferric chloride solution. The pattern may be used to couple thermoelectric elements in a thermoelectric device as illustrated in FIGS. 2A and 2B and discussed above. As another example, the pattern may be used to electrically couple components in a high power electronics application using the ceramic plate as a substrate. Other suitable pattern-forming techniques may be used.

At step 540, in some embodiments, the metallized ceramic may be plated. For example, nickel may be plated on the metallized ceramic to enhance soldering or brazing operations performed on the metallized ceramic. In some embodiments, a zincate step may be performed prior to plating at this step to improve adhesion of the one or more layers of plating performed at this step. The zincate step may be used to remove oxidation from the metallized portions of the ceramic and apply a layer of zinc to the metallized portions of the ceramic.

Although several embodiments have been illustrated and described in detail, it will be recognized that modifications and substitutions are possible without departing from the spirit and scope of the appended claims.

What is claimed is:

1. A method for forming a metallized ceramic comprising:
thermal spraying metal directly onto a first side of a ceramic plate, the metal comprising aluminum; and
densifying the thermally sprayed metal.

2. The method of claim 1, wherein thermal spraying metal onto the first side of the ceramic plate comprises arc spraying the metal.

3. The method of claim 1, wherein densifying the thermally sprayed metal comprises heating the ceramic plate under an inert cover gas.

4. The method of claim 1, further comprising creating a pattern on the ceramic plate by etching away one or more portions of the metal from the ceramic plate.

5. The method of claim 1, further comprising:
applying a mask to the ceramic plate before thermal spraying the metal onto the first side of the ceramic plate; and
removing the mask from the ceramic plate after thermal spraying the metal onto the first side of the ceramic plate.

6. The method of claim 1, further comprising plating a second metal onto the ceramic plate after thermal spraying the metal onto the first side of the ceramic plate.

7. The method of claim 6, wherein the second metal comprises nickel.

8. The method of claim 1, wherein densifying the thermally sprayed metal comprises heating the ceramic plate at a temperature above the melting point of the metal.

9. The method of claim 1, further comprising thermal spraying the metal onto a second side of the ceramic plate before densifying the thermally sprayed metal, wherein the first side and the second side are different.

10. The method of claim 1, further comprising:
coupling a plurality of P-type and N-type thermoelectric elements to the ceramic plate; and
coupling a second ceramic plate to the plurality of P-type and N-type thermoelectric elements.

11. A device comprising:
a ceramic plate;
at least one portion of metal directly bonded to a first side of the ceramic plate without an interface layer, the metal comprising aluminum; and
wherein the one portion of metal is configured to adhere to the ceramic plate while the at least one plate is in an environment with a temperature of at least 200 degrees Celsius.

12. The device of claim 11, further comprising a plurality of P-type and N-type thermoelectric elements coupled to the at least one portion of metal.

13. The device of claim 11, further comprising a second metal plated onto the at least one portion of metal.

14. The device of claim 13, wherein the second metal comprises nickel.

15. The device of claim 11, further comprising at least one second portion of metal directly bonded to a second side of the ceramic plate, wherein the first side and the second side are different.

16. A method comprising:
creating a metallization pattern on a ceramic plate by:
thermal spraying a first portion of metal directly onto a first side of the ceramic plate, the first portion of metal comprising aluminum; and
thermal spraying a second portion of metal directly onto a second side of the ceramic plate, the first side and the second side being different, the second portion of metal comprising aluminum; and
heating the ceramic plate at a temperature above the melting point of the first portion of metal and above the melting point of the second portion of metal after thermally spraying the first portion of metal and the second portion of metal.

17. The method of claim 16, wherein:
thermal spraying the first portion of metal comprises arc spraying the first portion of metal; and
thermal spraying the second portion of metal comprises arc spraying the second portion of metal.

18. The method of claim 1, wherein creating the metallization pattern on the ceramic plate further comprises etching away one or more parts of the first portion of metal and one or more parts of the second portion of metal from the ceramic plate.

19. The method of claim 1, wherein creating the metallization pattern on the ceramic plate further comprises:
applying a mask to the ceramic plate before thermal spraying the first portion of metal and the second portion of metal; and
removing the mask from the ceramic plate after thermal spraying the first portion of metal and the second portion of metal.

20. The method of claim 1, further comprising plating a second metal onto the ceramic plate after creating the metallization pattern on the ceramic plate.
